(19) United States
(12) Patent Application Publication
(10) Pub. No.: US 2003/0061766 A1
(43) Pub. Date: Apr. 3, 2003

(54) Polishing agent and method for producing planar layers

(76) Inventors: Kristina Vogt, Lohmar (DE); Dietrich Pantke, Ratingen (DE); Lothar Puppe, Burscheid (DE); Stephan Kirchmeyer, Leverkusen (DE)

Correspondence Address: BAYER CORPORATION, PATENT DEPARTMENT, 100 BAYER ROAD, PITTSBURGH, PA, 15205, US

(21) Appl. No.: 10/239,464

(22) PCT Filed: Mar. 19, 2001
(86) PCT No.: PCT/EP01/03113

(30) Foreign Application Priority Data
Mar. 31, 2000 (DE) 100 16 020.4
Dec. 21, 2000 (DE) 100 63 870.8

(51) Int. Cl. C09G 1/02; C09K 3/14

(52) U.S. Cl. 51/308; 106/3; 438/692; 438/693

(57) ABSTRACT

There is provided a process for polishing monocrystalline semiconductor materials of silicon and germanium to a high degree of surface perfection comprising polishing the material with a modified colloidal silica sol having a pH between about 11 to 12.5 and composed of colloidal silica particles which are coated with chemically combined atoms of aluminum to give a surface coverage of about 1 to about 50 aluminum atoms on the surface per 100 silicon atoms on the surface of uncoated particles. The particles of the modified silica sol used in the process of the invention have a specific surface area of about 25 to about 600 square meters per gram with the silica concentration of the sol ranging from about 2 to about 50% by weight.

The present invention relates to an SiO₂-based polishing abrasive and to a process for producing planar layers.

Integrated circuits (ICs) comprise patterned semiconductive, nonconductive and electrically conductive thin films. These patterned layers are usually produced by applying a layer material, for example by vapour deposition, and by patterning using a microlythographic process. The electronic circuit components of the IC, such as for example transistors, capacitors, resistors and interconnects, are produced by the combination of the various semiconductive, nonconductive and conductive layer materials.

The quality of an IC and its functioning are highly dependent on the precision with which the various layer materials can be applied and patterned.

However, as the number of layers increases, the planarity of the layers decreases considerably. Beyond a certain number of layers, this leads to the failure of one or more functional components of the IC and therefore to the failure of the entire IC.

The fall in the planarity of the layers is the consequence of the addition of new layers if these new layers are to be applied to layers which have already been patterned. Height differences, which may amount to up to 0.6 μm per layer, form as a result of the patterning. These height differences are cumulative from layer to layer and mean that the next layer is no longer applied to a planar surface, but rather to an uneven surface. A first consequence of this is that the next layer applied has an uneven thickness. In extreme cases, this leads to the formation of flaws, defects in the electronic functional components and defective contacts. Uneven surfaces also lead to problems with patterning. To be able to produce sufficiently small patterns, an extremely high depth of focus (DOF) is required in the microlithographic process step. However, these structures can only be sharply focussed in one plane; the greater certain points differ from this plane, the less sharp the focussing becomes.

To solve this problem, so-called chemical mechanical polishing (CMP) is carried out. CMP effects global planarization of the patterned surface by abrasion of elevated layer parts until a planar layer is obtained. As a result, the next layer can be added on a planar surface without height differences and the precision of patterning and the ability of the components of the IC to function are retained.

A CMP step is carried out with the aid of special polishing machines, polishing pads and polishing abrasives (polishing slurries). A polishing slurry is a composition which, in combination with the pad on the polishing machine, abrades the material to be polished.

An overview of the CMP technique is given in, for example, B. M. Mueller, J. S. Steckenrider Chemtech (1998) pp. 38-46.

CMP slurries decisively influence the polishing performance during the polishing process. Hitherto, it has been assumed that both chemical and mechanical operations are of influence. For this reason specific polishing slurries are required for various polishing steps.

In principle, a distinction is drawn between the polishing of non-conductive layers, e.g. of silica, and the polishing of electrically conductive layers, predominantly metals such as tungsten, aluminium and copper. The polishing of silica is known as oxide CMP.

Furthermore, in oxide CMP there is a series of different polishing steps which differ through the application of the silica in the respective layer structure and the number and type of layer materials involved in the layer structure.

An important step in the oxide CMP process is the so-called ILD (interlayer dielectric) polishing step, in which the silica which provides insulation between two interconnect levels is polished. Furthermore, however, the importance of further oxide CMP steps is increasing, for example the so-called STI (shallow trench isolation) step, in which isolating layers of semiconductor elements are polished.

Particularly in polishing steps which involve semiconductor layers, the demands imposed on the precision of the polishing step and therefore on the polishing slurry are particularly great.

A range of parameters which characterize the action of the polishing slurry represent an assessment scale for the efficacy of polishing slurries. These parameters include the abrasion rate, i.e. the rate at which the material to be polished is abraded, the selectivity, i.e. the ratio of the abrasion rates of material which is to be polished to other materials which are present, and parameters which represent the uniformity of planarization. Parameters used to represent the uniformity of the planarization are usually the within-wafer-nonuniformity (WIWNU) and the wafer-to-wafer nonuniformity (TWNU), as well as the number of defects per unit area. A wafer is a polished slice of silicon on which integrated circuits are constructed.

Strongly alkaline formulations of abrasive particles, such as alumina, silica and cerium oxide, are used as polishing slurries for oxide CMP, polishing slurries based on silica having become particularly widespread in practice.

The raw material for producing the polishing slurries is generally pyrogenic silica which comprises large aggregates of smaller primary particles, i.e. small, generally spherical primary particles are securely bonded in the pyrogenic silica to form larger, irregularly shaped particles. Therefore, to produce a polishing slurry it is necessary for these aggregates to be broken down into particles which are as small as possible. This is achieved by the introduction of shearing energy, e.g. by intensive agitation, in mixtures of water or alkaline media and pyrogenic silica. The shearing energy causes the aggregates of pyrogenic silica to be broken down. However, since the efficiency of introduction of the shearing energy is dependent on the particle size, it is not possible to produce particles of the size and shape of the primary particles using the shearing forces. Therefore, the polishing slurries produced in this way have the drawback that the aggregates are not fully broken down and aggregates of primary silica particles remain in the slurry. This coarse particle fraction may lead to the increased formation of scratches and other undesirable defects on the surface which is to be polished.

EP-A-899 005 teaches that the coarse particle fraction can be avoided by filtration, but this is complex and only partially solves the problem, since aggregates which are smaller than the filtration limit remain and, on account of their aspherical shape, may continue to damage the surface which is to be polished.

WO 96/027 2096, U.S. Pat. No. 5,376,222 and EP-A-520 109 teach the use of basic silica sols with a pH of between 9 and 12.5. This pH is set by the addition of alkali hydroxide or of amines.

These polishing slurries have the advantage that they practically only comprise discrete spherical particles, which only lead to low levels of scratches and other defects on the surface which is to be polished.

The drawback of these polishing slurries is their lower abrasion rate. It is aimed to compensate for this drawback by the increased addition of basic polishing accelerants, i.e. alkali hydroxide and amines. However, the chemical equilibria for silica impose limits on the addition of basic polishing accelerants when silica-based polishing slurries are used. Beyond a certain quantity of hydroxide ions, these ions react with the silica particles and lead to the formation of silicates (peptization). Therefore, polishing slurries with a pH of over 12 are unstable and can only be used with difficulty on an industrial scale.

In EP-A-874 036 and U.S. Pat. No. 5,876,490, it is attempted to solve these problems by providing the silica particles with coatings of polymers or cerium dioxide.

JP 09/324 174 proposes organic polymers and polysiloxanes for this purpose. Coatings of alumina are described in U.S. Pat. No. 3,922,393, and surface modifications for reduction of the silanol groups on the surface are described in U.S. Pat. No. 4,664,679.

As a result, the stability of polishing slurries based on silica particles is increased. However, according to current knowledge a certain amount of freely accessible silica surface is required in order to achieve sufficient abrasion rates. Even if hitherto not much has been known about the chemical processes which occur on the surface, there is an idea that these sphere surfaces are required in order to deposit the material which has been removed from the surface to be polished. Consequently, such polishing slurries, despite high quantities of polishing accelerants, present unsatisfactory polishing rates. Moreover, a surface treatment of the polishing abrasive particles makes the polishing slurry and therefore the entire IC fabrication process more expensive.

In Research Disclosure (RD) 419 020, it is described that, depending on the mean particle size, the best polishing results were obtained with silica sol particles with a mean size of 35 nm.

However, there continues to be a need for polishing slurries with improved properties. In particular, polishing slurries with a sufficiently high abrasion rate, a high selectivity in particular between silica and silicon nitride, a good planarizing action and low defect densities are desired for the STI step.

Surprisingly, this object is achieved by the provision of polishing abrasives based on silica sols with a bimodal particle size distribution.

This is surprising to the person skilled in the art, since it was known from RD 419 020 that silica sol particles with a mean particle size of 35 nm are said to have optimum polishing properties.

However, this is not the case. The polishing abrasives which have now been discovered have improved abrasion rates and increased selectivities compared to polishing abrasives from the prior art.

Therefore, the invention relates to polishing abrasives containing spherical, discrete silica particles which are not linked to one another via bonds, characterized in that the polishing abrasive contains

a) 5 to 95% by weight, preferably 20 to 80% by weight, silica particles of a size from 5 to 50 nm, and

b) 95 to 5% by weight, preferably 80 to 20% by weight silica particles of a size from 50 to 200 nm

with the proviso that the total set of particles has a bimodal particle size distribution.

Furthermore, the invention relates to processes for producing planar layers with the aid of these polishing abrasives.

The polishing abrasives according to the invention do not contain silica particles which are linked to one another via bonds. They have solids contents of from 1 to 60% by weight, preferably 1 to 30% by weight, particularly preferably 5 to 20% by weight, it being possible to set desired solids contents by the addition of water. In addition to silica particles, the polishing abrasives according to the invention may also contain further additives, such as for example polishing accelerants, surface-active substances or viscosity-adjusting compounds.

Silica sols form the basis of the polishing abrasives according to the invention. Silica sols contain silica particles which are not linked to one another via bonds. Silica sols are sedimentation-resistant, colloidal solutions of amorphous SiO₂ in water or alcohols and other polar solvents. They generally have a similar viscosity to water, and some of the commercially available products have high solids concentrations (up to 60% by weight) and are highly stable against gellation.

The silica sols range from milkily cloudy through opalescent to clear and colourless, depending on the particle size of the silica particles. The particles in the silica sols have diameters of from 5 nm to 250 nm, preferably 5 nm to 150 nm. The particles are spherical, spatially limited and are preferably electrically negatively charged. Inside the individual particles there is usually a skeleton of siloxane bonds which results from the linking of [SiO₄] tetrahedra or of polysilicic acids SiOH groups are often arranged on the surface. Stable silica sols with specific surface areas of approx. 30 to 1000 m²/g are preferred. The specific surface areas can be determined either using the BET method (cf. S. Brunauer, P. H. Emmet and E. Teller, J. Am. Chem. Soc., 1938, 60, p.309) on dried SiO₂ powder or directly in solution by titration as described by G. W. Sears (cf. Analytical Chemistry, Vol. 28, p. 1981, 1956).

The silica sols used usually have a viscosity of less than 10 mPa.s at a solids content of 30% by weight. The viscosity of the silica sols depends on the particle size, the electrolyte content, the silica content and the degree of crosslinking of the particles. The silica sols used are preferably uncrosslinked and are stable against gellation.

The stability against irreversible gellation to form the silica gel, which is based on three-dimensional crosslinking so as to form Si—O—Si bonds between the particles, falls as the silica content increases, the electrolyte contamination rises and the particle size decreases. In general, finely particulate silica sols (e.g. those with particle sizes of less than 6 nm) can only be set to lower solids concentrations (e.g. <30% by weight) than coarsely particulate silica sols (for example with particle sizes of greater than 50 nm), in which solids contents of up to 60% by weight can be achieved.

The pH of the silica sols used is between 1 and 12. The pH of the silica sols used is usually between 9 and 11. The range between pH 5 and pH 6 is less preferred, since in this range the stability of silica sols is only low. At pHs of over 12, the particles are increasingly peptized and dissociated so as to form alkali silicate solution.

Silica sols are unstable with respect to the addition of electrolyte, such as for example sodium chloride, ammonium chloride and potassium fluoride. For stabilization purposes, silica sols contain alkali, such as for example caustic soda or potash solution, ammonia or other alkalis. Therefore, silica sols without added electrolyte are preferred.

Silica sols can be obtained by condensation of dilute silicic acid solutions which have been freshly prepared from molecular silicate solutions, more rarely by peptization of silica gels or by other processes. Most of the processes for preparing silica sols which are carried out on an industrial scale use technical-grade water glasses as starting material.

Soda water glasses or potash water glasses are suitable for the process, soda water glasses being preferred for cost reasons. Commercially available soda water glass has a composition of Na₂O·3.34 SiO₂ and is usually produced by melting silica sand with soda or a mixture of sodium sulphate and coal, so that a transparent, colourless glass is obtained, known as piece glass. In comminuted form, this piece glass reacts with water at elevated temperature and pressure to form colloidal, strongly alkaline solutions which are then subjected to cleaning.

Processes in which finely particulate quartz or other suitable SiO₂ raw materials are broken down under hydrothermal conditions with alkalis directly to form aqueous water glasses are known.

To prepare the silica sols used in the polishing abrasives, it is necessary to remove the alkali metal cations from the water glass. The most customary method for removing alkali metals is to treat dilute water glass solutions with cation exchangers in the H⁺ form. Preferably, water glass solutions with a silica content of below 10% by weight are passed over exchanger columns. Short residence times in the exchange zone, in which the pH of the solutions is 5 to 7, are important in order to prevent gellation of the solutions and silicification of the ion-exchange resin.

The dilute silicic acid solution which is formed (known as fresh sol) is highly unstable and is preferably immediately stabilized and concentrated by renewed alkalization and by thermal treatment. The silica sol is particularly preferably stabilized by alkalization of the solution to a SiO₂:Na₂O ratio of 60 to 130:1, heating part of the solution at 60 to 100° C. in order to enlarge the particles and subsequently continuously adding fresh sol solution and allowing it to grow onto the existing particles. At the same time or subsequently, the solution can be concentrated to the desired concentration by evaporation.

By accurate control of the reaction, monitoring the pH and temperature or by controlled setting of the residence times, it is possible to set a desired particle size range. It is also possible to add so-called nuclear sols as well as the fresh sol. The nuclear sols used may be silica sols with defined particle size distributions.

It is also possible to prepare the silica sols used by further processes. For example, this preparation is possible by hydrolysis of tetraethyl orthosilicate (TEOS). Silica sols which are obtained using this process are of only limited use as a polishing abrasive in semiconductor fabrication, on account of their high price.

An extensive explanation of silica sols is given in K. K. Iler, The Chemistry of Silica, Chapter 4, pp. 312-461, Wiley & Sons, New York, 1979.

Silica sols which are prepared by the removal of alkali metals from water glasses followed by stabilization and which have a bimodal particle size distribution are preferred. The particle sizes of the silica sols used are in a distribution which contains 5-95% by weight, preferably 20-80% by weight, particles in a size distribution from 5-50 nm and 95-5% by weight, preferably 80-20% by weight, particles in a size distribution from 50 to 200 nm. The term bimodal means that there is at least one minimum between two maxima of the particle size distribution.

As well as electron microscope images, various other methods are also suitable for measuring the particle sizes in the nanometer range, such as for example laser correlation spectroscopy, ultrasound measurements or measurements using an ultracentrifuge. On account of its high sharpness of separation, the ultracentrifuge is particularly suitable for determining bimodal particle size distributions.

The particular feature of the ultracentrifuge is that the dispersion is fractionated according to particle size prior to the actual measurement. It is known that, in a homogeneous dispersion, the large particles form a sediment more quickly than the medium-sized and small particles which are also present. When the ultracentrifuge cell is irradiated with laser light, a clearly defined change in intensity occurs as a function of time. The change in concentration of the particles and, from this, the particle size distribution can be calculated from this change in intensity. The light source is a He-Ne laser. The ultracentrifuge allows a high level of accuracy, a high resolution, and the distributions can be determined precisely, which is particularly important with bimodal distributions.

Bimodal silica sols can be prepared by mixing monomodal silica sols. In this case, it is possible to set mixtures with different quantities of monomodal silica sols, one silica sol component having a particle size maximum between 5 and 50 nm and the second silica sol component having a particle size maximum between 50 and 200 nm. If appropriate, bimodal silica sols may also be prepared during the stabilization. It is preferable to prepare bimodal silica sols using a mixing process, since with this process the desired quantitative ratios can be set in a significantly more reproducible manner. The formulation of the sol to form a polishing slurry is carried out, for example, by dilution with water and possible addition of additives. Additives may be added in quantities of from 0.01% by weight to 10% by weight, based on the polishing slurry.

The polishing abrasive silica sols have pHs of preferably 9 to 12, particularly preferably from 10 to 11. The high pHs which are required to accelerate polishing can be established, for example, by the addition of alkali hydroxides, such as for example potassium hydroxide and sodium hydroxide, amines or ammonia or tetraalkylammonium hydroxides. Salts which undergo an alkaline reaction during the hydrolysis, such as for example sodium carbonate, sodium hydrogen carbonate, potassium carbonate, potassium hydrogen carbonate and ammonium hydrogen carbonate, are also suitable. Examples of suitable amines include primary amines, secondary amines, tertiary amines, heterocyclic amines, triamines, tetramines or pentamines. Examples for tetraalkylammonium hydroxides which may be used include tetramethylammonium hydroxide, tetraethylammonium hydroxide, tetrapropylammonium hydroxide and tetrabutylammonium hydroxide.

It is possible to add further agents for improving the performance of the polishing slurries: e.g. surface-active substances, such as alkyl sulphates, alkyl sulphonates, phenols, glycols or fluorosurfactants or, for example, viscosity-adjusting substances, such as polyelectrolytes, polyacrylic acids, polyethylene amines and polysiloxanes.

Surface-active substances are preferably anionic, cationic or nonionic low-molecular weight, oligomeric or polymeric emulsifiers, surfactants or protective colloids.

Examples of anionic low-molecular weight, oligomeric or polymeric emulsifiers orsurfactants are alkali metal or alkaline-earth metal salts of fatty acids, e.g. sodium salts of saturated fatty acids having from 10 to 21 carbon atoms, sodium salts of unsaturated fatty acids having 12 to 18 carbon atoms, alkyl ether sulphonates, such as ethers of sulpho-hydroxy-polyethylene glycols with, for example, 1-methylphenylethyl-phenol, nonylphenol, or with alkyl ethers having from 12 to 18 carbon atoms, aryl-alkyl-sulphonates, such as for example straight-chain- or branched-butyl-substituted naphthalenesulphonic acids or alkyl sulphates, such as the sodium salts of long-chain alkyl sulphates.

Examples of cationic low-molecular weight, oligomeric or polymeric emulsifiers or surfactants are the salts of amines which have long-chain alkane radicals and from 8 to 22 carbon atoms and have been reacted with acids or by alkylation to give the ammonium compounds, or also analogous phosphorus compounds and analogous sulphur compounds.

Examples of nonionic oligomeric or polymeric emulsifiers or surfactants are alkyl polyglycol ethers or alkyl polyglycol esters, for example long-chain alcohols having ethoxylated saturated or unsaturated bonds, e.g. having from 12 to 18 carbon atoms, ethoxylated castor oil, ethoxylated (coconut) fatty acids, ethoxylated soya bean oil, ethoxylated resin acids or ethoxylated rosin acids, ethoxylated and, if desired, propoxylated butyl diglycol, or ethoxylated alkyl aryl ethers, such as ethoxylated straight-chain and/or branched nonylphenol or octylphenol or bennylated p-hydroxybiphenyl, ethoxylated triglycerides and diglycerides and alkyl polyglycosides.

Other suitable emulsifiers or surfactants are ethoxylated long-chain alkyl-or alkenylamines, lecithin, reaction products of polyethylene glycols and diisocyanates which have been modified with long-chain alkyl isocyanates, reaction products of rapeseed oil and diethanolamine or ethoxylated reaction products of sorbitan and long-chain alkane- or alkenecarboxylic acids.

Moreover, so-called protective colloids are suitable, such as for example polyvinyl alcohols or water-soluble cellulose derivates, such as methylcellulose.

The invention is explained below with reference to examples, the polishing abrasive according to the invention not being restricted to the examples mentioned.

### EXAMPLES

### Example 1

### Preparation of a Bimodal Silica Sol

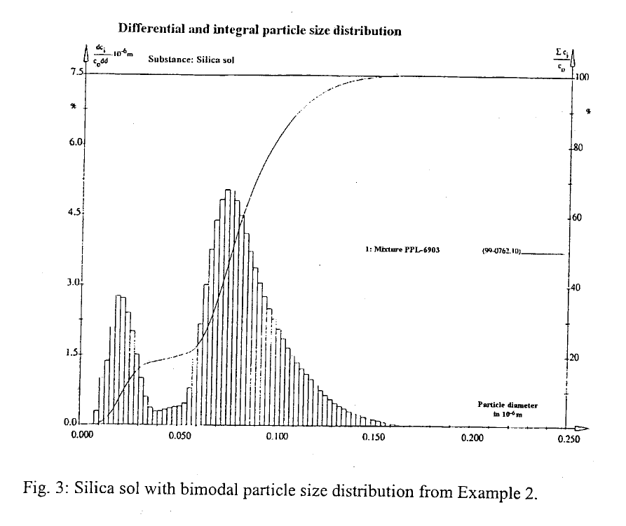

500 ml of a silica sol with a mean particle size of 15 nm and a pH of 9.3 are mixed at room temperature with 1583 ml of a silica sol with a mean particle size of 70 nm and a pH of 9.4. The bimodal particle size distribution of this silica sol can be seen from FIG. 3. This bimodal silica sol with a pH of 9.4 is used for the polishing test in Example 2.

### Examples 2 to 4

### Polishing Tests

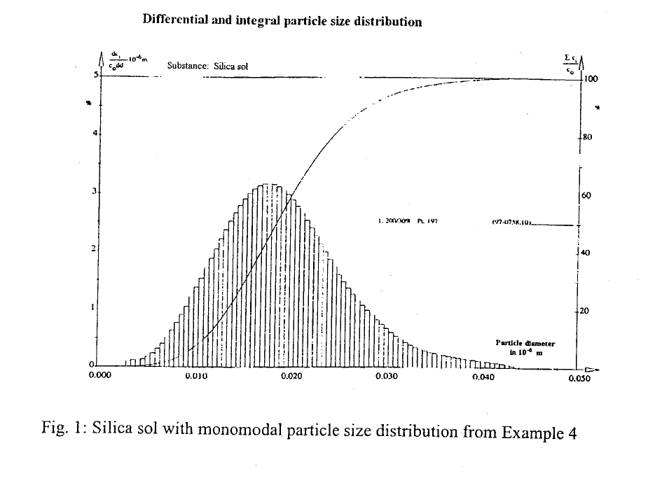

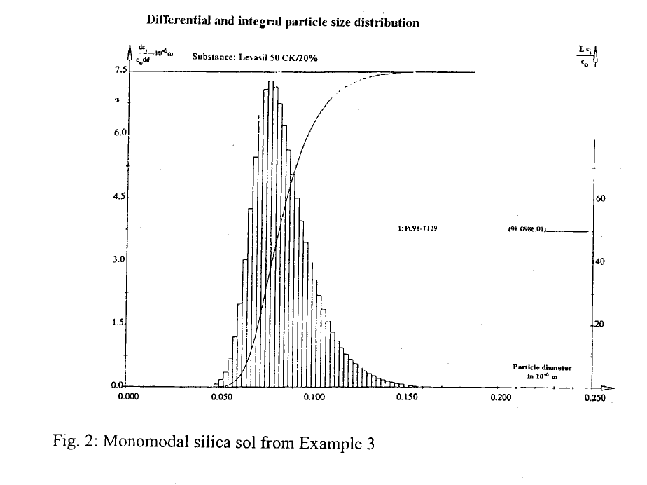

Examples 2 to 4 together with the abrasion rates and selectivities of the silica sols according to the invention and the comparative silica sols are listed in the table. The polishing conditions are summarised below. In Example 2, the results of the polishing test using the polishing slurry with the bimodal silica sol according to the invention from Example 1 are given in Example 2. A silica sol with a mean particle size of 70 nm (FIG. 2) is used for the polishing slurry in polishing test 3. The polishing slurry in polishing test 4 contains a finely particulate silica sol with a mean particle size distribution of 15 nm (FIG. 1).

Polishing conditions for the tests

| Polishing machine: | IPEC 472 | |
|---|---|---|
| Pressure: | 0.5 | bar |
| Counterpressure: | 0 | bar |
| Plate speed: | 32 | rpm |
| Support speed: | 28 | rpm |
| Metering rate of the polishing slurry | 175 | ml/min |
| Polishing time: | 1 | min |

| | |
|---|---|
| Polishing pad: | Rodel IC 1400 |

Unpatterned (blanket) wafers with a diameter of 200 mm are used. The thickness of the oxide layer (TEOS) is 10,000 Angstrom and the thickness of the nitride layer is 6000 Angström.

The abrasion rate for the oxide (TEOS) is given in Angström per minute, and the selectivity indicates the ratio of the oxide to the silicon nitride.

Table: Abrasion rates and selectivity of polishing slurries which contain silica sol

| | Abrasion rate | Selectivity |
|---|---|---|
| Polishing slurry | [Angström/min] | oxide/nitride |
| Example 2 | 3051 | 8.0 |
| Bimodal silica sol | | |
| Particle size distribution | | |
| (FIG. 3) | | |
| Comparative example 3 | 2857 | 6.6 |
| Monomodal silica sol | | |
| Particle size distribution | | |
| (FIG. 2) | | |
| Comparative example 4 | 2109 | 4.0 |
| Monomodal silica sol | | |
| Particle size distribution | | |
| (FIG. 1) | | |

As can be seen from the test results given in the table, the polishing slurry with the bimodal silica sol according to the invention from Example 1 has a significantly higher abrasion rate and an improved selectivity compared to the two polishing slurries used in the comparative examples, each with monomodal silica sols.

1. Polishing abrasive containing spherical, discrete silica particles which are not linked to one another via bonds, characterized in that the polishing abrasive contains
a) 5 to 95% by weight silica particles of a size from 5 to 50 nm, and
c) 95 to 5% by weight silica particles of a size from 50 to 200 nm
with the proviso that the total set of particles has a bimodal particle size distribution.

2. Polishing abrasive according to claim 1, characterized in that the polishing abrasive contains
a) 20 to 80% by weight silica particles of a size of from 5 to 50 nm, and
b) 80 to 20% by weight silica particles of a size of from 50 to 200 nm.

3. Polishing abrasive according to claims 1 and 2, characterized in that the polishing abrasive has a pH of from 9 to 12.

4. Polishing abrasive according to claims 1 to 3, characterized in that the polishing abrasive has a solids content from 1 to 60% by weight.

5. Polishing abrasive according to claims 1 to 4, characterized in that the polishing abrasive has been obtained by mixing monomodal silica sols with different particle sizes.

6. Polishing abrasive according to claims 1 to 5, characterized in that the polishing abrasive has a selectivity of from 6 to 15.

7. Process for producing planar oxide layers, characterized in that a polishing abrasive according to claims 1 to 5 is used.
